(19) United States
(12) Patent Application Publication
(10) Pub. No.: US 2018/0190804 A1
(43) Pub. Date: Jul. 5, 2018

(54) GATE-INDUCED SOURCE TUNNELING FIELD-EFFECT TRANSISTOR

(71) Applicant: THE REGENTS OF THE UNIVERSITY OF CALIFORNIA, Oakland, CA (US)

(72) Inventors: Chi On CHUI, Encino, CA (US); Andrew Samuel PAN, Pacific Palisades, CA (US)

(73) Assignee: THE REGENTS OF THE UNIVERSITY OF CALIFORNIA, Oakland, CA (US)

(21) Appl. No.: 15/740,309

(22) PCT Filed: Jun. 30, 2016
(86) PCT No.: PCT/US2016/040474

§ 371 Date: Dec. 27, 2017

Related U.S. Application Data
(60) Provisional application No. 62/188,217, filed on Jul. 2, 2015.

(51) Int. Cl. H01L 29/739; H01L 29/49; H01L 29/06

(52) U.S. Cl. CPC H01L 29/7391; H01L 29/0673; H01L 29/4983

(57) ABSTRACT

A tunneling field-effect transistor includes: 1) a source region; 2) a drain region; 3) a channel region extending between the source region and the drain region; 4) a gate electrode spaced from the channel region; and 5) a dielectric layer disposed between the gate electrode and the channel region. The gate electrode includes a first section including a first conductive material M1 and a second section including a different, second conductive material M2, and the first section is electrically connected to the second section.

### CROSS REFERENCE TO RELATED APPLICATION

This application claims the benefit of U.S. Provisional Application Ser. No. 62/188,217, filed on Jul. 2, 2015, the content of which is incorporated herein by reference in its entirety.

### TECHNICAL FIELD

This disclosure generally relates to field-effect transistors and, more particularly, tunneling field-effect transistors.

### BACKGROUND

Currently, electronic systems are constrained in the minimum amount of power consumed by the fundamental carrier transport constraints of existing metal-oxide-semiconductor field-effect transistors (MOSFETs). Tunneling devices, such as tunneling field-effect transistors (TFETs), are a new direction for electronics to overcome this constraint and realize ultralow power electronics. TFETs are desirable because in principle their use of gate modulated interband tunneling should allow for extremely low leakage currents and steep subthreshold swings (SS), allowing operation at much lower voltages (and hence lower power levels) than conventional transistors. In practice, however, major challenges still impede the progress of such devices, including low on-currents, n- and p-device asymmetry, large-scale reproducibility and variability challenges, and parasitic leakage. Many of these challenges are due to the material- and doping profile-related difficulties in realizing high quality tunneling junctions at the source-channel interface.

For example, TFETs using small band gap III-V materials are highly desirable for increasing drive current and reducing supply voltage. However, p-type TFETs, which include n-doped sources, face two significant obstacles: 1) low active donor concentrations (on the order of about 10¹⁹ cm⁻³ for many III-V bulk materials and even lower for nanostructures due to solid solubility, incomplete ionization, or defect compensation constraints, and 2) low conduction band (CB) density of state (DOS). Low doping lengthens the tunneling length and strongly reduces drive current, while strong carrier degeneracy due to low DOS degrades the SS by increasing the contribution of “thermal tail” states in the source distribution function. As a result, various experimental III-V TFETs are n-type. Since p-type devices are to be included for complementary circuits, their unavailability would impede the use of TFETs for logic applications. Furthermore, in both n- and p-type TFETs, the current can be highly sensitive to the position and abruptness of the doping profile, which are difficult to control precisely. This leads to poor nominal performance and increased variability due to random dopant fluctuations (RDF). Disorder induced by heavy doping also creates band tails, which can significantly worsen the SS.

It is against this background that a need arose to develop the embodiments described herein.

### SUMMARY

In some embodiments, a TFET includes: 1) a source region; 2) a drain region; 3) a channel region extending between the source region and the drain region; 4) a gate electrode spaced from the channel region; and 5) a dielectric layer disposed between the gate electrode and the channel region. The gate electrode includes a first section including a first conductive material M1 and a second section including a different, second conductive material M2, and the first section is electrically connected to the second section.

In additional embodiments, a TFET includes: 1) a source; 2) a drain; 3) a channel extending between the source and the drain; 4) a gate electrode spaced from the channel; and 5) a dielectric layer disposed between the gate electrode and the channel. The gate electrode includes a first section adjacent to the source and a second section adjacent to the drain, and the first section and the second section include different materials forming a heterojunction between the first section and the second section.

In further embodiments, a transistor operation method includes: 1) providing a TFET including: a) a source region; b) a drain region; c) a channel region extending between the source region and the drain region; and d) a gate electrode spaced from the channel region by a dielectric layer, wherein the gate electrode includes a first section and a second section, the first section and the second section include different materials forming a heterojunction between the first section and the second section; and 2) applying a common gate voltage to the first section and the second section to induce a tunneling junction within the channel region and spaced from the source region and the drain region.

Other aspects and embodiments of this disclosure are also contemplated. The foregoing summary and the following detailed description are not meant to restrict this disclosure to any particular embodiment but are merely meant to describe some embodiments of this disclosure.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1: Gate-induced source tunneling field-effect transistor (GISTFET) in a double-gate (DG) design. M1 and M2 are shorted and biased together by a gate voltage, but their work function (WF) difference sets up a tunneling junction between lightly doped channel sections C1 and C2.

FIG. 2: Band diagrams along a p-type GISTFET channel as V_{g} decreases, assuming local equilibrium. Vertical arrows: energy interval. Dashed (dot) lines: ΔΨ_{c}. Horizontal solid arrows: tunneling lengths. Dashed (bar) lines: source and drain quasi-Fermi levels. Insets: corresponding bias points on the device I_{d}−V_{gs} curve.

FIG. 3a: GISTFET in a tri-gate or a FinFET design.

FIG. 3b: GISTFET in a gate-all-around design.

FIG. 4: Simulated I_{d}−V_{gs} for InAs DG GISTFETs (solid lines) and TFETs (dashed lines) with different abrupt source doping concentrations Nₛ. The gate oxide is 3 nm-thick HfO₂, and the channel thickness is 4 nm for all devices. L_{M1}=5 nm and L_{M2}=25 nm for GISTFETs, while TFETs have a gate length of 30 nm and a metal WF of 5.4 eV. The increasing current at positive V_{gs} is due to drain-side tunneling, as no drain underlap is employed.

FIG. 5: Minimum source-side tunneling lengths as a function of gate bias for GISTFET and TFET devices with different source doping.

FIG. 6: GISTFET band diagrams and spectral currents densities in the off-state at V_{gs}=0.2 V and V_{ds}=0.5 V for (a) Nₛ=5×10¹⁸ cm⁻³ and (b) Nₛ=2×10¹⁹ cm⁻³. Horizontal lines (labeled by arrows): source and drain Fermi energies.

FIG. 7: Band diagram and the local density of states (LDOS) along the channel of a GISTFET with Nₛ=5×10¹⁸ cm⁻³, L_{M1}=5 nm, L_{M2}=25 nm, and V_{ds}=−0.5 V for (a) V_{gs}=0.2 V, (b) V_{gs}=0 V and V_{ds}=−0.5 V, (c) V_{gs}=−0.5 V, and (d) V_{gs}=−0.8 V, corresponding to the semiclassical operating regions in FIG. 2. Horizontal lines (labeled by arrows): source and drain Fermi energies. White lines: lowest conduction and valence subbands. Vertical lines: separation between C1 and C2. LDOS is shown on a log scale.

FIG. 8: Simulated I_{d}−V_{gs} for InAs DG GISTFETs (solid lines) and TFETs (dashed lines) with different channel and oxide thicknesses t_{ch} and tₒₓ. The source doping Ns is 5×10¹⁸ cm⁻³ for the GISTFETs and 2×10¹⁹ cm⁻³ for the TFETs, respectively, with other device characteristics as in FIG. 4.

FIG. 9: Device structure and band diagram for a) proposed GISTFET and b) conventional TFET. Analytical formulas for tunneling distance in GISTFET (assuming L_{M1}=L_{M2}=L) and TFET are shown as well. Note the independence of the former from source doping Nₛ and its dependence on work function difference ΔΦ.

FIG. 10: Device band diagrams and LDOS in linear scale along a channel for p-type GISTFET biased in a) off-state, b) subthreshold, c) on-state and d) negative differential conductance (NDC) regimes, each corresponding to the bias regions in the I-V curve of FIG. 11. Both C1 and C2 are undoped or lightly doped; accumulation and depletion hence is relative to adjacent contact doping (n-type doping in source, p-type doping in drain).

FIG. 11: Sample I-V curve for p-type GISTFET with separate bias regimes marked corresponding to band diagrams in FIG. 10. A phosphorene channel is assumed.

FIG. 12: Dependence of tunneling distance on electrostatic scaling length λ and ΔΦ for GISTFETs and source doping Nₛ for TFETs, based on analytic equations in FIG. 9 for a band gap of 0.5 eV.

FIG. 13: a) Atomic structure of monolayer phospherene. b) Non-equilibrium Green's function (NEGF) I-V of phosphorene devices without (E_{g}=1.6 eV, ΔΦ=2 eV) and with strain (E_{g}=0.8 eV under 8% biaxial strain, ΔΦ=1.1 eV). Band structures are fitted from density functional theory (DFT) calculations.

FIG. 14: Contact doping concentration dependence of monolayer strained phosphorene GISTFET and TFET. All devices are strained with same geometry as in FIG. 13; Φ₁=4 eV and Φ₂=5.1 eV for GISTFETs.

FIG. 15: Dependence of I-V characteristics on work function difference Al dependence in strained phosphorene GISTFETs.

FIG. 16: NEGF I-V characteristics of n-type and p-type InAs GISTFETs and TFETs. Contact doping=5×10¹⁸ cm⁻³ for all GISTFETs, while n-TFET Nₛ=10²⁰ cm⁻³ and p-TFET Nₛ=2×10¹⁹ cm⁻³ in accord with material solid solubility limits. Middle inset: GISTFET DG structure.

FIG. 17: Doping and geometric dependence of InAs DG devices. Nₛ is given in units of cm⁻³ and t_{ch} and tₒₓ in units of nm. Note the more pronounced improvement in GISTFET with oxide scaling due to stronger dependence on electrostatic integrity.

FIG. 18: Gate length scaling dependence of InAs GISTFETs (L₁/L₂) and TFETs (L_{g}) in nm. Nₛ=5×10¹⁸ cm⁻³ for both GISTFETs and TFETs in this comparison. Note that no drain underlaps are simulated, increasing off-state leakage.

### DETAILED DESCRIPTION

Embodiments of this disclosure are directed to an improved device, a gate-induced source tunneling field-effect transistor (GISTFET), which uses multiple (e.g., 2 or more) gate work functions to modulate lateral tunneling. In some embodiments, the device operates through the use of electrostatic gating via metal heterojunctions to define and control tunneling and to decouple tunneling from a chemical dopant junction. The performance of the device is largely independent of details of a chemical doping profile, thereby freeing device design from issues related to solid solubility, junction abruptness, and dopant variability. This is in contrast to other TFETs, where a tunnel junction is defined at least in part by chemical doping, which imposes severe constraints on achievable performance which are circumvented by the improved device of embodiments of this disclosure. The GISTFET is applicable for various types of tunneling devices, including steep SS, high current p-type transistors. The GISTFET and its variants can be used for other steep SS transistors and for applications where negative differential conductance (NDC) is desired, for example, in bistable logic or analog circuits.

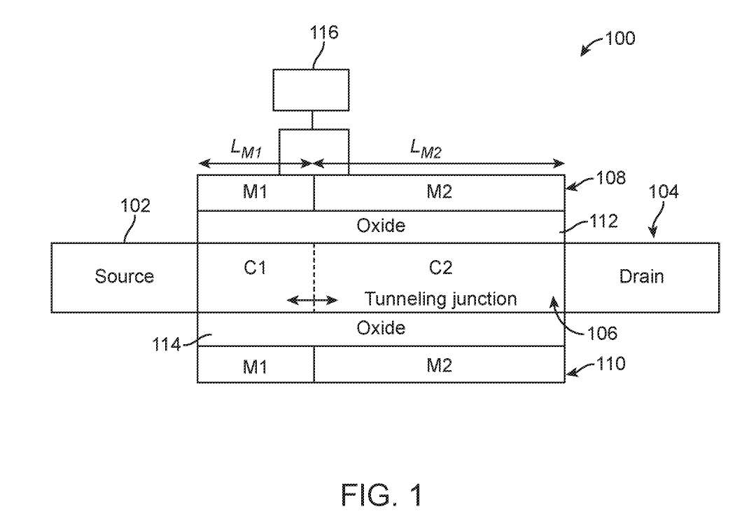

An embodiment of a GISTFET 100 is shown in FIG. 1. By way of example, the illustrated embodiment is a double-gate (DG) p-type TFET; however, additional embodiments can be directed to other multi-gate transistor structures, single-gate or planar transistor structures, n-type transistors and other device architectures, such as ultra-thin body (UTB) devices, tri-gate transistors, FinFETs, nanowire FETs, gate-all-around transistors, vertical transistors, multichannel transistors, and so forth. The GISTFET 100 has a lateral TFET architecture, and a semiconductor region of the device is comprised of doped source and drain regions 102 and 104 and a channel region 106, which may be lightly doped or undoped. The doping polarity of the source and drain regions 102 and 104 are opposite and may be chosen based on the intended application of the device; for example, for p-FET operation, the source region 102 can be doped n-type and the drain region 104 can be doped p-type, whereas for n-FET operation, the source region 102 can be doped p-type and the drain region 104 can be doped n-type. Each gate electrode (of a pair of gate electrodes 108 and 110) is separated from the semiconductor channel region 106 by a thin oxide layer 112 or 114 (or other dielectric layer). Instead of being composed of a homogeneous material, each gate electrode 108 or 110 is comprised of two different metals M1 and M2 (within respective sections of each gate electrode 108 or 110), which are electrically shorted or connected together, forming a heterojunction whose interface occurs substantially perpendicular to the channel region 106 (or substantially parallel to a tunneling junction within the channel region 106) as illustrated, although other orientations of the heterojunction and the tunneling junction are encompassed by this disclosure. The metals M1 and M2 are selected to have different work functions (WFs) Φ₁ and Φ₂ such that:

ΔΦ=Φ₂−Φ₁>E_{g,QC}+qV_{dd} (1)

where E_{g,QC} is the quantum confined band gap of the channel material, namely the gap between the lowest subbands of the conduction band (CB) and valence band (VB), q is the elementary charge, and V_{dd} is the maximum operating voltage. M1 and M2 are electrically shorted or connected together and share the same external gate bias, which is applied by a voltage source 116. The channel sections “under” M1 and M2 are referred as C1 and C2, respectively; the (bias-dependent) potential energy difference between them specifies the relevant tunneling junction and is denoted by ΔΨ_{c}. For each individual channel section C1 or C2, the gate bias can strongly modulate the potential when the channel section is in depletion (namely, the electron and hole quasi-Fermi levels lie deeply in the band gap), but weakly if the channel section is in accumulation or strong inversion (such that one quasi-Fermi level is degenerate, leading to “electrostatic doping”). Modulation of ΔΨ_{c} arises because the different metal WFs offset the gate voltage thresholds for which C1 and C2 pass between accumulation, depletion, and inversion. Although not shown, additional voltage sources and electrical contacts and interconnects can be included to provide suitable bias to the source and drain regions 102 and 104.

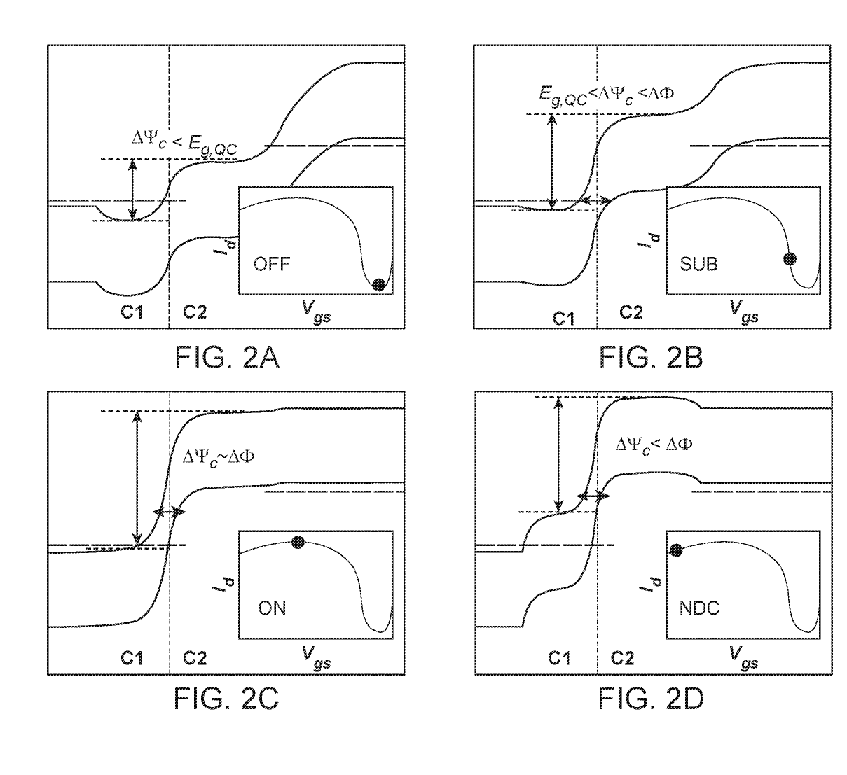

The resulting bias stages of device operation are schematically indicated by the band diagrams of an embodiment in FIG. 2. It is assumed in the following discussion that scattering is strong and quantization weak enough such that local equilibrium holds, and semiclassical carrier distributions can be described by local quasi-Fermi levels throughout the device. Ballistic and quantum effects can lead to quantitative changes, although the basic operating principle remains applicable. In the off-state a), C1 is pulled by M1 into electron accumulation, partially pinning the channel potential, and C2 is in depletion but ΔΨ_{c}<E_{g,QC}, suppressing tunneling. As V_{g} becomes more negative b), the C2 energy bands are pulled up, and interband tunneling occurs once ΔΨ_{c} exceeds E_{g,QC}. With further gate bias c), C1 passes from accumulation to depletion, and ΔΨ_{c} reaches a maximum value close to ΔΦ. Eventually d), the valence band edge of C2 crosses the drain Fermi level and undergoes hole accumulation, causing ΔΨ_{c} to decrease; this leads to a drop in current and hence NDC. However, if eq. 1 is fulfilled this occurs at biases well outside the operating range of the device.

The design of the GISTFET 100 allows tunneling-based transistors to be fabricated that can overcome previously encountered constraints and operate at substantially lower voltage and power. Because the tunneling junction is electrostatically induced in the lightly doped (or undoped) channel region 106 and controlled by ΔΦ, the tunneling length is decoupled from the placement and magnitude of the source doping. Also, because the tunneling junction is not defined by doping but rather metal gate WFs (which are substantially independent of the channel semiconductor properties), complementary operation is readily achievable. The design of the GISTFET 100 avoids the previously described challenges in creating heavily doped abrupt junctions, such as due to solid solubility constraints. Furthermore, because the doped source and drain regions 102 and 104 are present to contact bias electrodes rather than to define the tunneling junction, their doping level in the GISTFET 100 becomes secondary and does not strongly affect performance. Also, because the source doping can be kept relatively low, the adverse effects of degeneracy and low DOS on the SS can be alleviated. While the lower source doping may increase series resistance, the latter should not be a constraining factor for the low power applications in which tunneling devices are likely to be used. Therefore the use of electrostatic doping, as implemented in the GISTFET 100, can be particularly suitable for realizing high performance III-V p-TFETs. High currents and steep SS can be achieved without requiring optimization of the chemical doping magnitude or abruptness, considerably easing the fabrication constraints for the GISTFET 100 compared to other TFETs.

Qualitatively, the advantage of the GISTFET 100 over another TFET can be explained by comparing their electrostatic properties. The potential drop near the junction of a gated TFET channel occurs over a distance set by the characteristic length λ, which is determined by structural parameters of the device and sets its electrostatic integrity. For instance, for the surface potential in DG devices:

$$λ = \sqrt{\frac{{ϵ}_{ch} {t}_{ch} {t}_{ox}}{2 {ϵ}_{ox}}} \qquad ( 2 )$$

where c_{ch} and cₒₓ are the channel and oxide permittivities, and t_{ch} and tₒₓ are the channel and oxide thicknesses, respectively. In another TFET, the potential drop across the source-side tunneling junction is divided between the gated channel and the depletion region in the source region, so it extends over a distance on the order of λ+wₛ, where wₛ is the source depletion width set by the doping profile. By contrast, both sides of the tunneling junction in the GISTFET 100 are gated, so the potential drop ΔΨ_{c} occurs over a distance equal to about twice the characteristic electrostatic length 2λ. Approximately, when λ<wₛ, the potential barrier will become narrower in the GISTFET 100 and its tunneling current can then exceed that of another TFET. Referring to eq. 2, this indicates that the GISTFET 100 becomes comparatively more desirable as the channel thickness or gate oxide thickness and permittivity are scaled. λ can also be reduced by using tri-gate or nanowire structures with stronger gate electrostatic control. By contrast, electrically active doping concentrations are not readily scalable and may even be reduced from their bulk values in nanostructures, making doping-centric architectures for improving tunneling performance more difficult to implement. It is noted that in isolation, body thickness scaling in TFETs and GISTFETs may be counterproductive past a certain point because size quantization effects may increase the band gap E_{g,QC} and reduce tunneling.

The GISTFET operating principle and specifications differ from other multiple WF designs for TFETs, as the latter primarily employ different metals to reduce drain leakage, and the device operation still relies on a heavily doped source region. In contrast to devices that rely on spatially varying gate oxides, the GISTFET of some embodiments uses asymmetry in the metal gate to replace and improve the operational source tunneling junction and to induce the tunneling junction in the channel away from the source and drain regions, rather than degrade the parasitic drain tunneling junction. Another doping-less device involves narrowly spaced and separately gated accumulation and inversion layers, which increase the tunneling length and raise the possibility of unwanted contact shorting. Instead of using separately biased metal gates to modulate tunneling, the GISTFET of some embodiments uses a commonly biased gate with different metals electrically connected together. Also, in the GISTFET of some embodiments, the tunneling junction width is ultimately modulated by the (potentially atomically) abrupt M1/M2 interface, rather than a lithographically defined separation between the source region and gate, thereby improving device performance as well as easing demands on fabrication.

Another design is an electron-hole bilayer (EHB) TFET, which uses “vertical” tunneling between accumulation and inversion layers on opposite sides of an undoped channel body. However, since EHB tunneling occurs perpendicular to the gate, field-induced quantum confinement (FIQC) effects can be large, and the lowest FIQC valence subband is heavy hole-like, reducing the gate efficiency and current. By contrast, charge transport in the GISTFET of some embodiments occurs along an unconfined direction substantially parallel to a surface of a gate, where FIQC is negligible, and the lowest valence states are light hole-like, increasing the tunneling probability. It is emphasized that a particular difference between the GISFET of some embodiments and the doping-less or EHB TFETs arises because the former leverages the difference between the M1/M2 WFs (instead of asymmetric applied voltages) to directly define the tunneling junction, not just to shift a threshold voltage.

By reducing the role of chemical dopants, the GISTFET of some embodiments greatly simplifies the associated design and processing considerations. The oxide quality and abruptness of the M1/M2 interface can impact GISTFET performance; in particular, metal intermixing and effects of WF pinning or variability should be reduced, depending on material system and processing conditions. Complementary metal-oxide-semiconductor (CMOS)-compatible metal combinations are also desired with work function differences fulfilling eq. 1, which can be on the order of about 1 eV in practice; combinations of Ti or Al (with work functions of about 4 eV), with Pt, Ni, or W (with work functions greater than about 5 eV) may be desirable in this regard. It is also noted that evaluation of as-deposited bilayer metal stacks indicates that the change in WF can occur within just a few atomic monolayers (e.g., <about 1 nm) across the heterointerface. In general, assuming an abrupt metal heterojunction, device performance improves with increasing ΔΦ, since larger WF differences will lead to higher lateral electric fields between C1 and C2 and hence shorter tunneling distances.

In the embodiment illustrated in FIG. 1, the channel region 106 is homogeneously composed of a single material. However, additional embodiments can be composed of multiple semiconductors, for example, by creating a semiconductor heterojunction in the channel region 106 substantially in parallel with the metal heterojunction in the gate 108 or 110. This can lead to higher currents or other improved performance metrics by further tuning the tunneling barrier in the channel region 106. In further embodiments, the source and drain regions 102 and 104 can be metal Schottky contacts rather than doped semiconductor regions, provided the Schottky resistance is smaller than the tunneling junction resistance between C1 and C2.

More generally, a TFET of some embodiments of this disclosure includes: 1) a source region; 2) a drain region; 3) a channel region extending between the source region and the drain region; 4) a gate electrode spaced from the channel region; and 5) a dielectric layer disposed between the gate electrode and the channel region. The gate electrode includes a first section formed of, or including, a first conductive material M1 and a second section formed of, or including, a different, second conductive material M2, and the first section is electrically connected to the second section.

In some embodiments, the channel region is formed of a semiconductor having a bandgap E_{g}, and M1 and M2 have respective work functions Φ₁ and Φ₂ such that an absolute difference between the work functions |Φ₂−Φ₁| is greater than E_{g}. For example, the absolute difference between the work functions |Φ₂−Φ₁| can be greater than about 0.2 eV, at least about 0.25 eV, at least about 0.3 eV, at least about 0.4 eV, at least about 0.5 eV, at least about 0.6 eV, at least about 0.7 eV, at least about 0.8 eV, at least about 0.9 eV, at least about 1 eV, at least about 1.1 eV, at least about 1.2 eV, at least about 1.3 eV, or at least about 1.4 eV, and up to about 1.5 eV, up to about 1.6 eV, or more.

In some embodiments, the TFET is a p-type TFET, Φ₂ is greater than Φ₁, the first section is adjacent to the source region, the second section is adjacent to the drain region, the source region is n-doped, and the drain region is p-doped. In some embodiments of the p-type TFET, an extent of source doping is up to or less than about 2×10¹⁹ cm⁻³, up to or less than about 1×10¹⁹ cm⁻³, up to or less than about 5×10¹⁸ cm⁻³, or up to or less than about 1×10¹⁸ cm⁻³. In some embodiments, the TFET is a n-type TFET, Φ₁ is greater than Φ₂, the source region is p-doped, and the drain region is n-doped.

In some embodiments, one of M1 and M2 is, or includes, Al (or aluminum) or Ti (or titanium), and another one of M1 and M2 is, or includes, Pt (or platinum), Ni (or nickel), or W (or tungsten). Other metals, metal nitrides, metal alloys, or other electrically conductive materials have suitable work functions can be included. For example, at least one of M1 or M2 can be, or can include, TiₓTa_{y}Al_{z}N. In some embodiments, one of M1 and M2 is, or includes, a conductive material, and another one of M1 and M2 is, or includes, an electrolyte, for use in, for example, sensing applications.

In some embodiments, the TFET further includes a voltage source connected to the gate electrode, and configured to apply a common gate voltage to the first section and the second section. In some embodiments, application of the common gate voltage is configured to induce a tunneling junction within the channel region. In some embodiments, M1 and M2 form a heterojunction within the gate electrode, and the tunneling junction is aligned with the heterojunction.

In some embodiments, a length L_{M1} of the first section is the same as or different from a length L_{M2} of the second section. For example, L_{M1}<L_{M2}, or L_{M1}>L. In some embodiments, the tunneling junction is spaced from the source region by a distance corresponding to about L_{M1}. In some embodiments, the tunneling junction is spaced from the drain region by a distance corresponding to about L_{M2}.

In some embodiments, the gate electrode and the dielectric layer correspond to a first gate electrode and a first dielectric layer, respectively, and the TFET further includes a second gate electrode spaced from the channel region, and a second dielectric layer disposed between the second gate electrode and the channel region. The second gate electrode includes a third section formed of a third conductive material M3 and a fourth section formed of a different, fourth conductive material M4, and the third section is electrically connected to the fourth section. In some embodiments, M3 is the same as M1, and M4 is the same as M2.

In some embodiments, the channel region is formed of a Group III-V semiconductor. In some embodiments, the channel region is formed of a Group IV semiconductor. In some embodiments, the channel region is formed of a two-dimensional or layered semiconductor. Other examples of semiconductors include semiconducting polymers, Group IV elements, Group IV binary alloys, Group II-VI binary alloys, Group IV ternary alloys, Group II-VI ternary alloys, Group III-V ternary alloys, Group III-V quaternary alloys, Group III-V quinary alloys, Group I-VII binary alloys, Group IV-VI ternary alloys, Group V-VI binary alloys, Group II-V binary alloys, and other binary, ternary, quaternary, or higher order alloys.

In some embodiments, the channel region includes a first section formed of a first semiconductor S1 and a second section formed of a different, second semiconductor S2. In some embodiments, S1 and S2 form a heterojunction within the channel region.

In some embodiments, the drain region includes a lightly doped region adjacent to the channel region, and a heavily doped contact region adjacent to the lightly doped region, for the purpose of reducing leakage current.

In some embodiments, the TFET has a SS no greater than about 50 mV/dec, no greater than about 45 mV/dec, no greater than about 40 mV/dec, no greater than about 35 mV/dec, no greater than about 30 mV/dec, no greater than about 25 mV/dec, or no greater than about 20 mV/dec, at an applied voltage in the range of ±0.05 V to ±1 V.

In some embodiments, the TFET has an on-current of at least about 0.01 A/cm, at least about 0.05 A/cm, at least about 0.1 A/cm, at least about 0.5 A/cm, at least about 1 A/cm, at least about 1.5 A/cm, at least about 2 A/cm, at least about 2.5 A/cm, or at least about 3 A/cm, at an applied voltage in the range of ±0.05 V to ±1 V.

In some embodiments, the TFET has an on-off current ratio of at least about 1×10⁵, at least about 5×10⁵, at least about 1×10⁶, at least about 5×10⁶, at least about 1×10⁷, at least about 5×10⁷, at least about 1×10⁸, at least about 5×10⁸, or at least about 1×10⁹, at an applied voltage in the range of ±0.05 V to ±1 V.

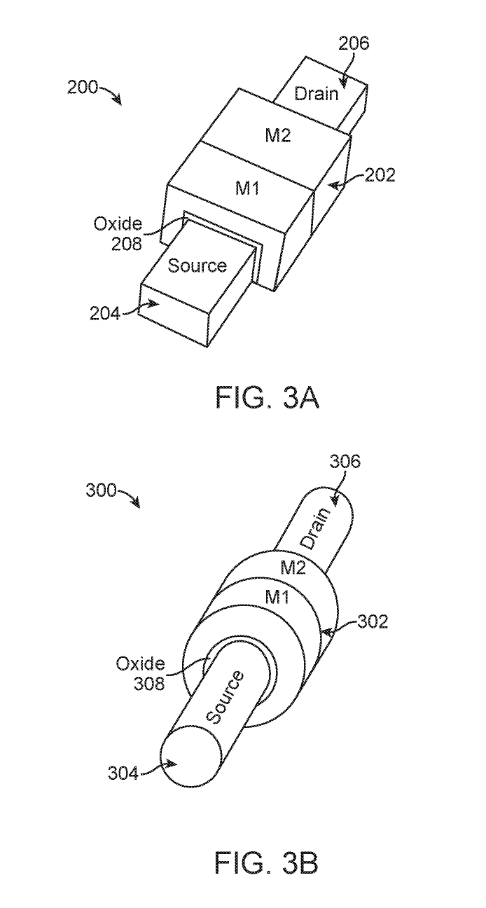

In some embodiments, the gate electrode and the dielectric layer cover multiple surfaces of the channel region. For example, the gate electrode and the dielectric layer can cover two, three, or more surfaces of the channel region (see FIG. 3a of an embodiment of a GISTFET 200, in which a gate electrode 202 and a dielectric layer 208 cover three surfaces of a channel region extending between a source region 204 and a drain region 206). In some embodiments, the gate electrode and the dielectric layer enclose, encircle, or surround the channel region (see FIG. 3b of an embodiment of a GISTFET 300, in which a gate electrode 302 and a dielectric layer 308 surround a channel region extending between a source region 304 and a drain region 306).

### EXAMPLES

The following examples describe specific aspects of some embodiments of this disclosure to illustrate and provide a description for those of ordinary skill in the art. The examples should not be construed as limiting this disclosure, as the examples merely provide specific methodology useful in understanding and practicing some embodiments of this disclosure.

### Example 1

To demonstrate the proposed device design, ballistic non-equilibrium Green's function (NEGF) simulations are performed of InAs TFETs and GISTFETs with varying levels of source doping. Details of the simulator are set forth in A. Pan and C. O. Chui, “Modeling direct interband tunneling. II. Lower dimensional structures,” J. Appl. Phys., vol. 116, p. 054509, August 2014, which is incorporated herein by reference. For computational efficiency, a four-band k·p Hamiltonian is used to describe InAs, neglecting spin-orbit effects; this may underestimate the current by giving a larger effective band gap compared to full band tight-binding predictions but suffices for qualitative comparisons. The simulated devices are DG structures like the one shown in FIG. 1.

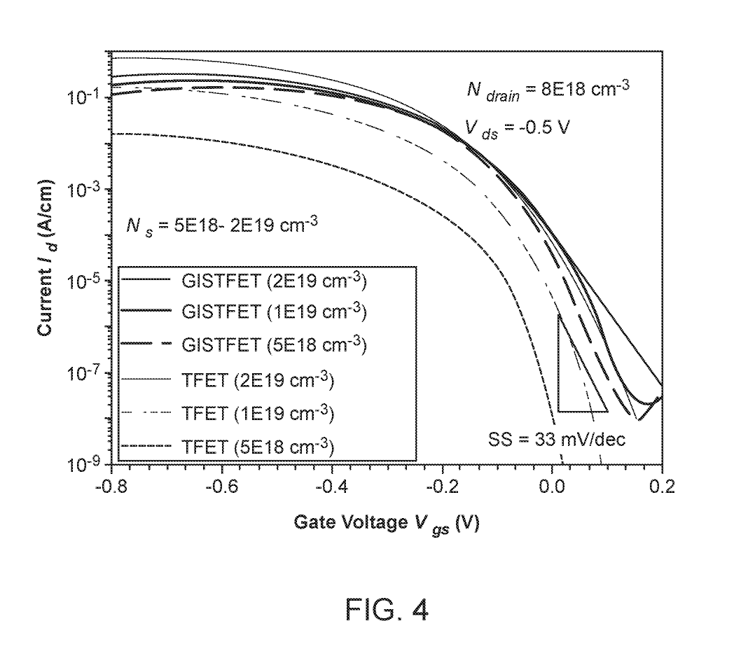

The GISTFETs are simulated using Φ₁=4 eV and Φ₂=5.4 eV, which can be achieved experimentally using Al and Pt, for instance. The results are shown in FIG. 4 and demonstrate several important characteristics. First, while the TFET Iₒₙ varies by almost two orders of magnitude with a 4× change in source doping, the GISTFET Iₒₙ is substantially independent of source doping and about equal to that of the Nₛ=2×10¹⁹ cm⁻³ TFET (which is a doping level that may already exceed the solid solubility limit of donors in InAs). Secondly, both the TFET and GISTFET SS tend to degrade somewhat with increased Nₛ because of the low DOS of InAs. Therefore, low n-type source doping levels are desirable for p-GISTFETs to combine steep SS with high current. As an example, the Nₛ=5×10¹⁸ cm⁻³ GISTFET provides an on-off ratio of about 10⁷, minimum SS of about 33 mV/dec, and Iₒₙ of about 13 μA/μm over an about 0.5 V bias range (between about 0.1 to about −0.4 V), comparable in performance to that of the 2×10¹⁹ cm⁻³ TFET. Finally, the sensitivity of threshold voltage to Nₛ is significantly less for GISTFETs compared to TFETs due to the greater influence of the source doping-dependent built-in voltage on the latter; this indicates that RDF-induced variability will be smaller for GISTFETs.

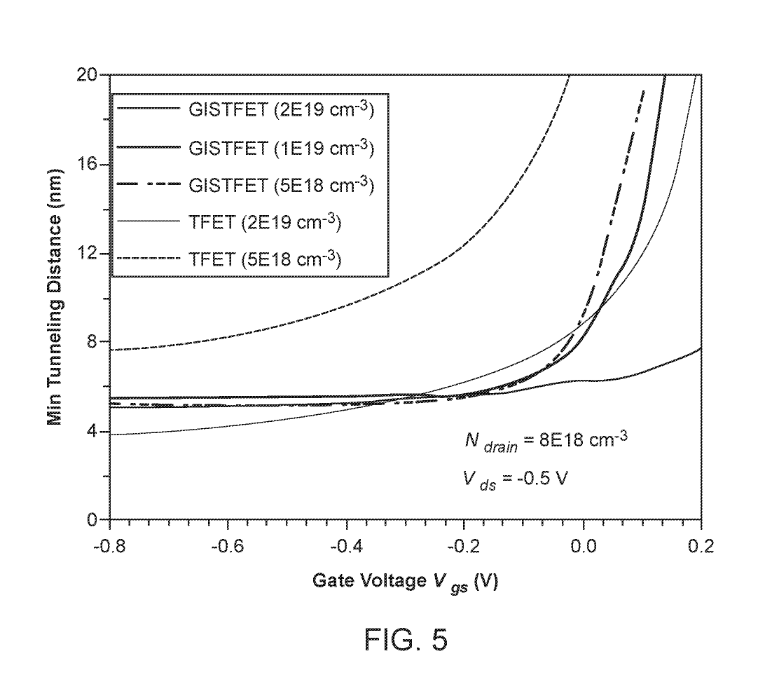

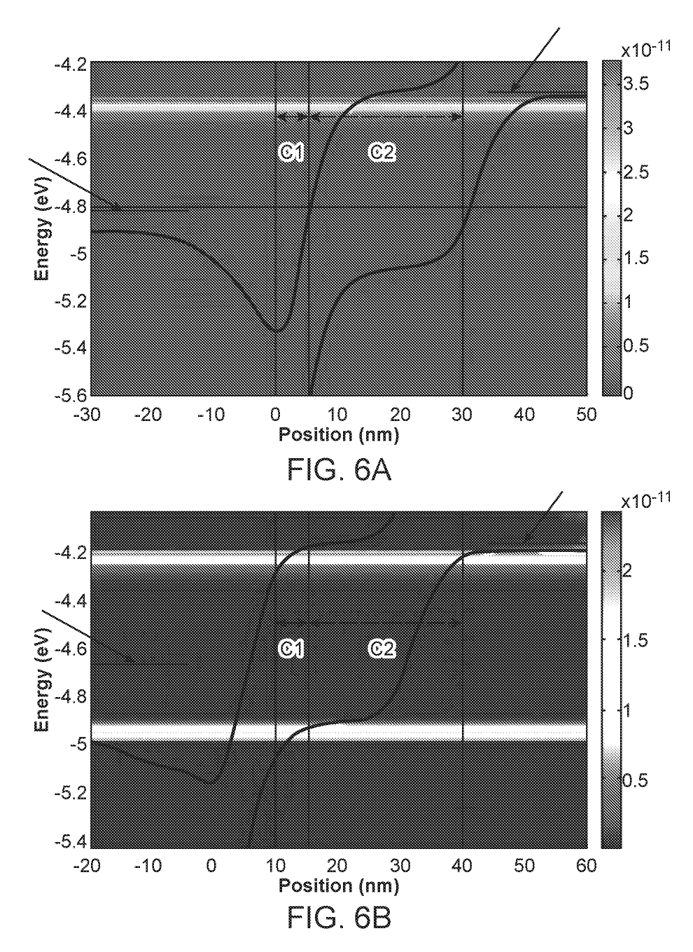

To understand these characteristics in more depth, in FIG. 5 the doping- and bias-dependent minimum tunneling lengths are extracted for the simulated TFETs and GISTFETs, specified as the shortest distance between CB and VB subband edges for energies above the lowest conduction subband energy in the source. It is observed that as the devices turn on (V_{gs}<−0.1 V), the tunneling lengths are virtually identical for the different GISTFETs since the C1/C2 junction electrostatics are substantially independent of doping, whereas the longer depletion regions at lower source doping lengthen the TFET tunneling distances. At low gate bias, however, the tunneling length is significantly shorter for highly doped GISTFETs. This is because the higher degeneracy of heavily doped GISTFETs increases the source Fermi level and leads to an effective threshold voltage shift, such that overlap of the source CB and channel VB edges still occurs up to V_{gs} of about 0.2 V. This can be observed by examining the band diagrams and spectral currents within the lowest and highest doped GISTFETs in the off-state in FIG. 6. Whereas substantially all the current in the Nₛ=5×10¹⁸ cm⁻³ device flows via tunneling at the C2/drain interface (and thus can be suppressed using lower drain doping, underlaps, and so forth), a separate current path also occurs near the source in the Nₛ=2×10¹⁹ cm⁻³ GISTFET due to energetic overlap of band states in C2 and the source.

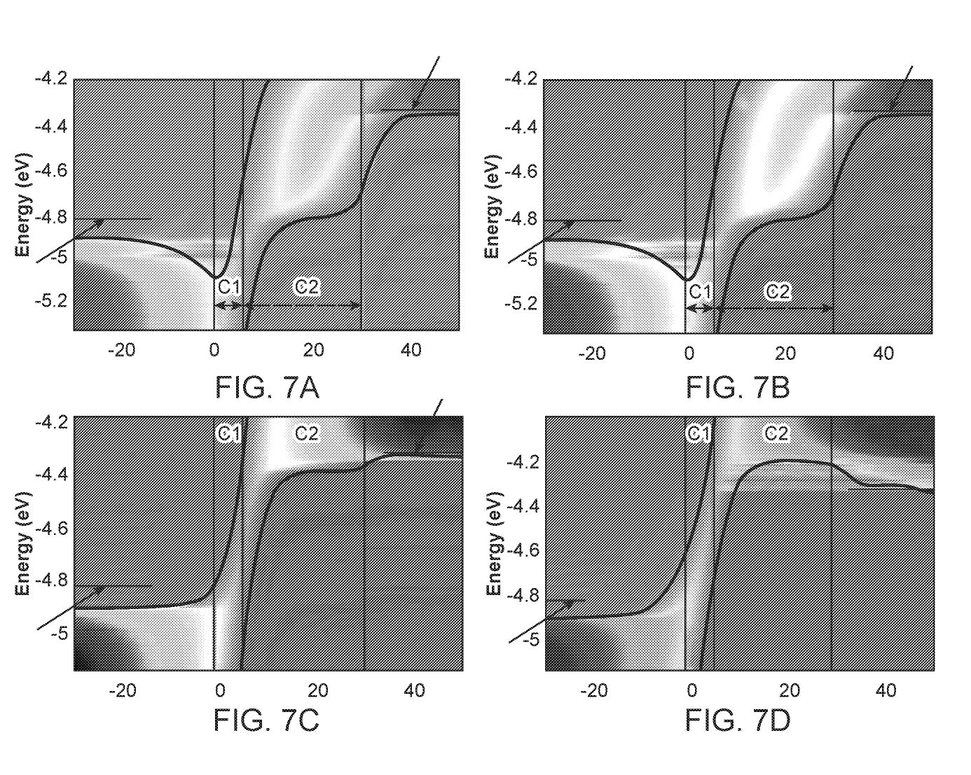

One may expect via inspection of the band diagrams in FIG. 6 that source-side tunneling should still occur in the low doped GISTFET at the selected voltage, since it is observed that the C2 VB in the off-state is below the CB edge of the source, but not that of C1. The reason why no detectable tunneling current flows at these energies is due to quantization effects and the assumption of ballistic transport. This can be best understood by examining the local density of states (LDOS) for the GISTFET in the off- and on-states, shown in FIG. 7. In the off-state a), the narrow electrostatically induced potential well causes spatially localized states to appear at energies below the source CB edge as indicated by the narrow lines in the LDOS; the effects of such states can be properly analyzed using intrinsically quantum mechanical simulations like NEGF. (In actuality the well is an effective 1-D electrostatically gated quantum “wire” because of the spatial confinement of the DG structure.) Tunneling may be expected to occur between energetically overlapping states within the C1 well and the C2 VB. However, the C1 states are spatially localized and hence cannot support carrier flow unless they can couple to continuum, current-carrying states on either side. Because these states lie in the band gap of the source, no continuous elastic transport process connects them to the source electrode and no detectable current will flow through them. Therefore, in the ballistic condition, once the VB edge of C2 falls below the source CB edge, source-side tunneling ceases.

If inelastic scattering occurs, for instance via optical or short wavelength acoustic phonons, it can couple the C1 localized states to the continuum CB and provide a continuous current path. Inclusion of inelastic scattering may therefore increase the off-state leakage current by allowing parasitic tunneling through the localized states in C1. Further evaluation can be carried out to quantify and assess these effects, which can be relevant for GISTFETs as well as other types of TFETs where localized accumulation regions appear. Qualitatively, these effects can be less important in III-V GISTFETs with narrow C1 channel lengths and high mobilities because of weaker electron-phonon coupling. In principle, provided proper metal work functions are selected, the threshold of the device can be shifted such that no detectable C1/C2 overlap occurs in the off-state.

The behavior of the off-state in the nanoscale GISTFET is therefore affected by the presence of ballistic and quantum effects. In subthreshold and the on-state, the band bending and device operation are consistent with semiclassical behavior, as shown in FIGS. 7b) and c), while the NDC region behaves as the obverse of the off-state as is seen from FIG. 7d). It is noted that the ballistic simulations underestimate one potential benefit of the GISTFET because the simulations do not account for self-energy corrections due to impurity scattering, which if fully incorporated would create a DOS tail in the heavily doped source and further degrade the SS of conventional TFETs. This effect should be negligible in the GISTFET since the doped regions are separated from the tunneling junction, giving it another comparative advantage.

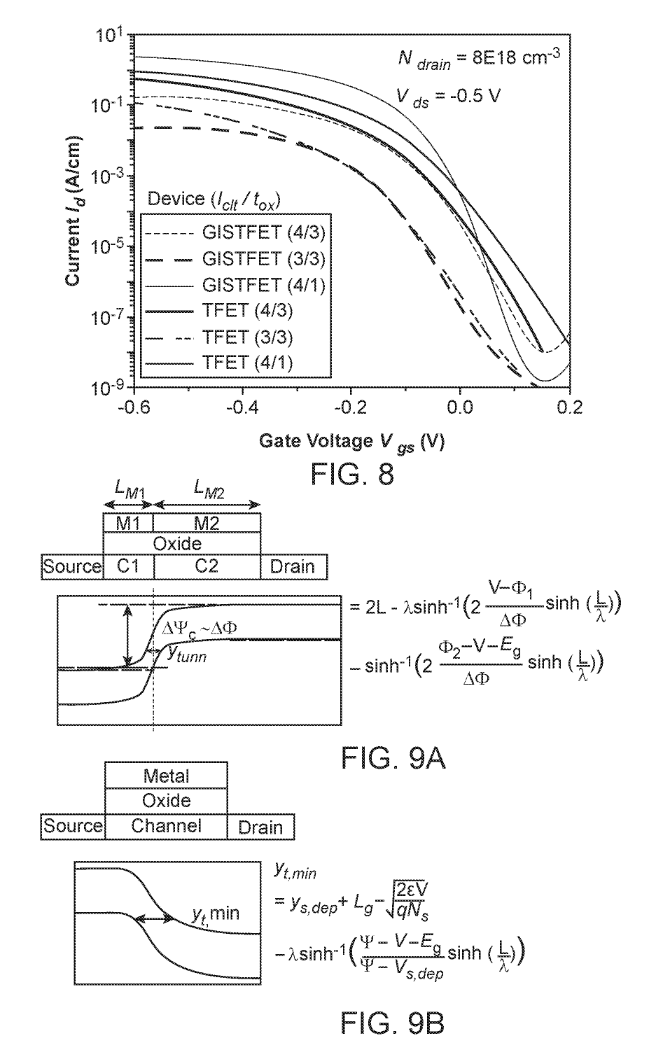

As an illustration of how device structure affects performance, GISTFETs and TFETs are simulated with different channel and oxide thicknesses as shown in FIG. 8. Interestingly, all else being equal, performance degrades for both device types if channel thickness is reduced because the band gap increases rapidly for very thin InAs devices, suppressing tunneling current. However, the GISTFET undergoes a significantly larger performance boost than the TFET when oxide thickness is scaled down. This shows the potential scaling benefits of the GISTFET. Overall, the use of gate-induced electrostatic coupling offers greater benefits from better gate control, small E_{g} materials, and low V_{dd} operation, which are also the primary development goals for TFETs. Device performance can be further optimized if a heterojunction can be aligned in the channel alongside the M1-M2 interface, which might be achievable using a vertical device layout. Finally, two-dimensional (2-D) or layered semiconductors, such as graphene nanoribbons or transition metal dichalcogenides like MoTe₂, are also promising GISTFET channel candidates due to their very small k.

By way of summary, this example has demonstrated the design for tunneling transistors, the GISTFET, which allows high performance complementary devices by utilizing gate metal heterojunctions, and their accompanying work function offsets, rather than chemical doping to induce interband tunneling. Quantum transport simulations confirm the operating principle of the device as well as subtleties related to quantization effects near the C1/C2 junction. Of note, the numerical results show that GISTFETs exhibit substantially improved p-type characteristics compared to conventional TFETs.

### Example 2

Introduction

TFETs face challenges in realizing high quality tunnel junctions due to doping profile-related difficulties related to solid solubility, junction abruptness, p versus n asymmetry, and dopant variability. An improved steep SS device is proposed to resolve these problems, the GISTFET, which uses a contiguous gate metal heterojunction to define a tunnel junction, decoupling conduction from a chemical doping profile. Its advantages are demonstrated over conventional TFETs with NEGF device simulations using 2-D phosphorene and InAs. The GISTFET fully utilizes the device scaling-driven improvements in electrostatic control to realize genuinely complementary steep SS transistors, free of doping profile-imposed operating constraints.

Device Operation

Current TFETs utilize tunneling junctions between a heavily doped source and a gated channel. The dependence on chemical doping leads to a number of difficulties, including constraints on solid solubility, junction abruptness, and random dopant fluctuations (RDF). These problems are especially important for materials like III-V or 2-D semiconductors with low dopant solubility or other difficulties in effective chemical doping. Therefore, it is proposed to replace the doping defined tunnel junction with an electrostatically induced one via a gate metal heterojunction; a schematic structure of an embodiment of this GISTFET device is shown in FIG. 9. The gate is comprised of two metals M1 and M2 with work functions (WFs) Φ₁ and Φ₂ such that ΔΦ=Φ₂−Φ₁>E_{g}, the channel material band gap. The different threshold voltages of channel regions C1 and C2 underneath the corresponding metals induce a tunneling junction with potential drop ΔΨ_{c}. Complementary n-type and p-type devices are made by reversing the contact polarity and position of M1 and M2. Because the doped source and drain are present to contact bias electrodes rather than define the tunneling junction, their doping becomes secondary.

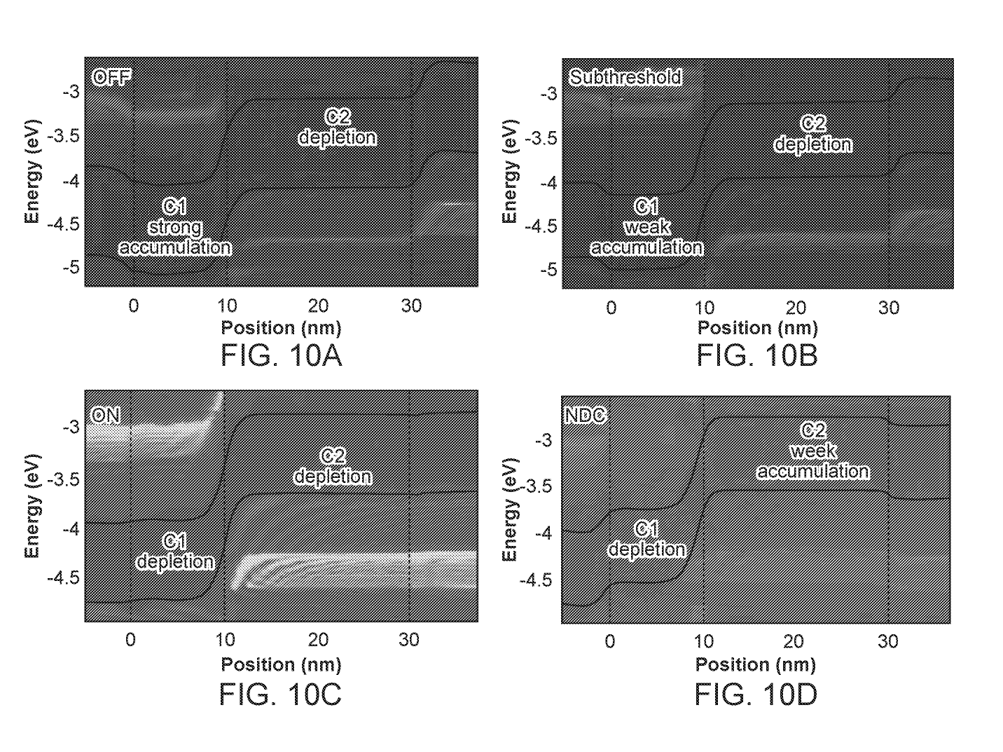

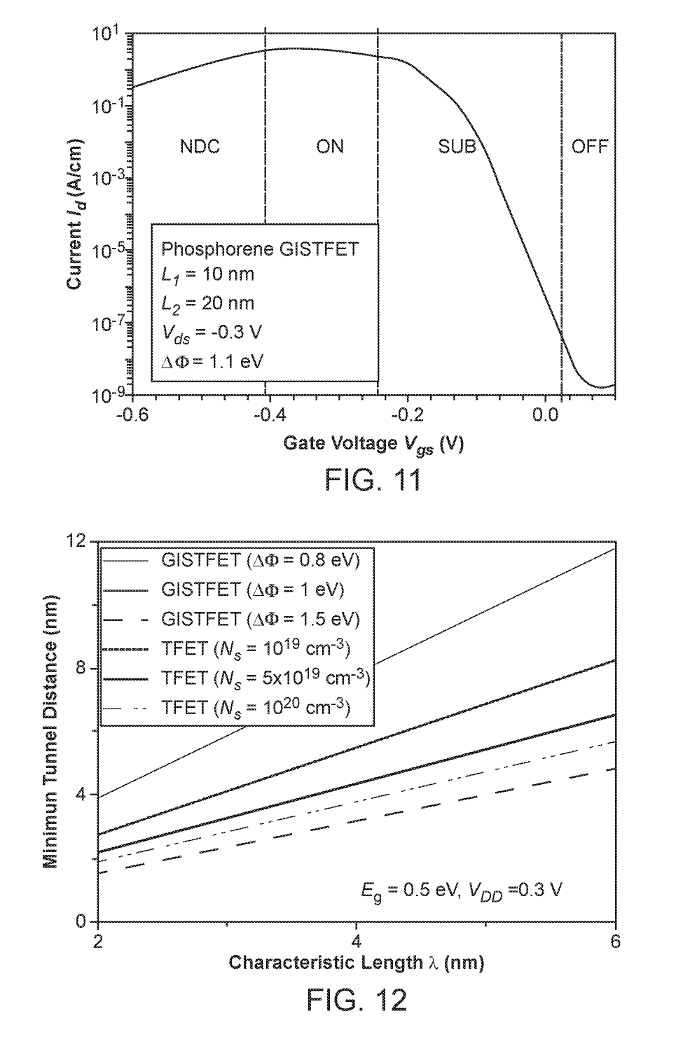

At a given bias, C1 and C2 may (separately) be in carrier accumulation or depletion, which modulates ΔΨ_{c} and tunneling probability between the off- and on-state, as illustrated in FIGS. 10 and 11. At high bias, negative differential conductance (NDC) may occur due to accumulation in C2, which may be useful in bistable operation applications. For other logic, provided ΔΦ>E_{g}+|qV_{dd}| where V_{dd} is a supply voltage, NDC occurs at biases well outside the operating range and thus has little practical impact. Because the junction is electrostatically induced in the lightly doped channel region and controlled by ΔΦ, the tunneling length is decoupled from the source doping. To verify this, analytical studies of the electrostatics are performed, and FIG. 12 shows how the tunneling distance scales versus characteristic length λ (setting device electrostatic integrity) and Al in GISTFETs and source doping Nₛ in TFETs. Because the tunneling junction is controlled by the gate in GISTFETs, its operation is largely independent of chemical doping and improves rapidly with lower λ and higher ΔΦ, matching or exceeding the performance of realistically doped TFETs. Note that the donor solid solubility for many III-V materials is about 10¹⁹ cm⁻³, severely constraining performance for p-type TFETs in particular, whereas field-effect induced carrier densities are not solubility constrained.

GISTFET Case Studies in Phosphorene and InAs

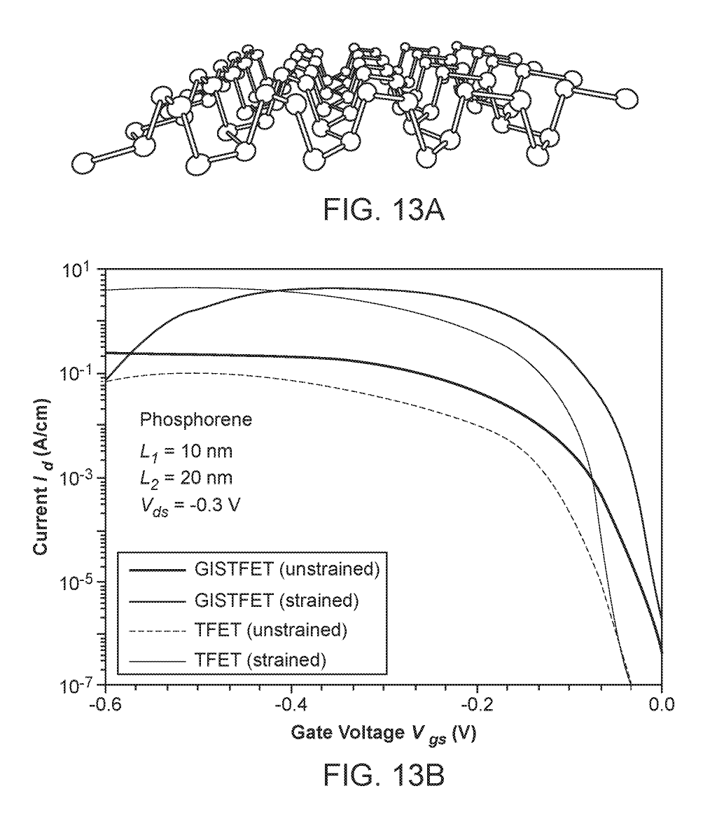

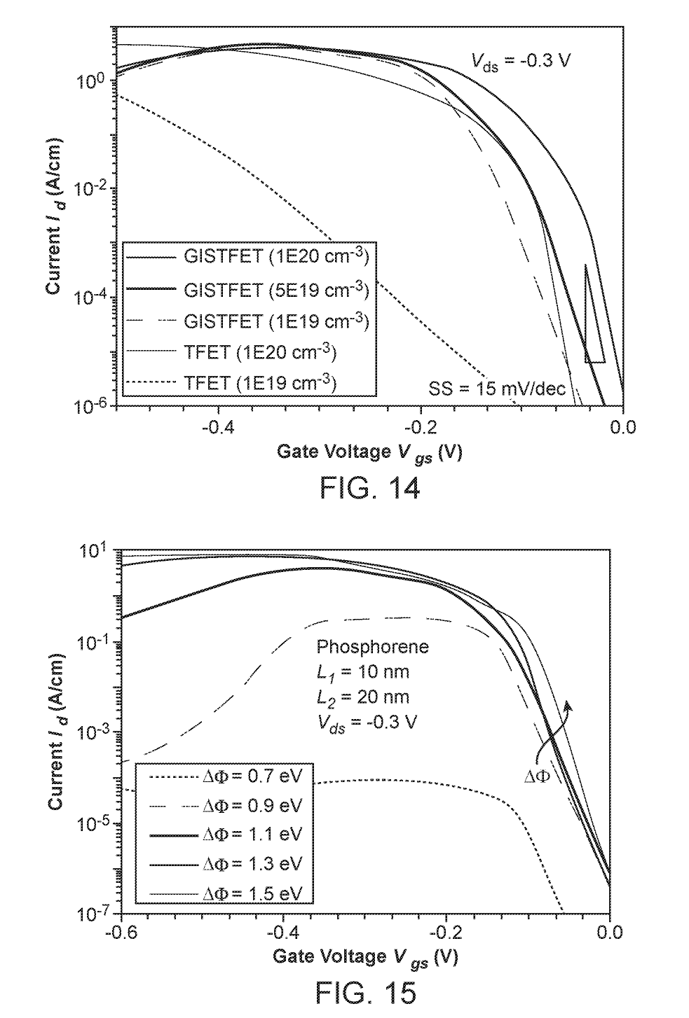

2-D semiconductors are desirable for GISTFETs because of their strong electrostatic control (very small λ<1 nm). Monolayer phosphorene is particularly desirable because of its low effective mass and strain-tunable band gap. NEGF simulations of phosphorene devices are performed using k·p Hamiltonians fitted to density functional theory (DFT) band structures from the literature. In FIG. 13, GISTFETs and TFETs are compared using unstrained and 8% biaxially strained phosphorene (which can withstand up to about 30% stain); the latter case leads to higher performance due to smaller band gap and therefore is used as the basis for subsequent calculations. In FIG. 14, phosphorene devices are compared using different Nₛ, and it is observed that the current and SS performance of the GISTFET generally exceeds those of TFETs, with much weaker doping dependence. High Iₒₙ of about 1-3 A/cm with SS of about 15 mV/decade are observed for the GISTFET at |V_{dd}| of about 0.3 V. In these devices, a WF difference ΔΦ=1.1 eV is used, which corresponds to using, for instance, Al or Ti for M1 and Pd or Ni for M2. In FIG. 15, the device performance is examined as a function of WF difference ΔΦ. It is observed that once the operating condition ΔΦ>E_{g}+|qV_{dd}|=1.1 eV is reached, performance is high and relatively WF independent, aside from the leftward shift of the NDC region with ΔΦ due to the increased range of ΔΨ_{c}.

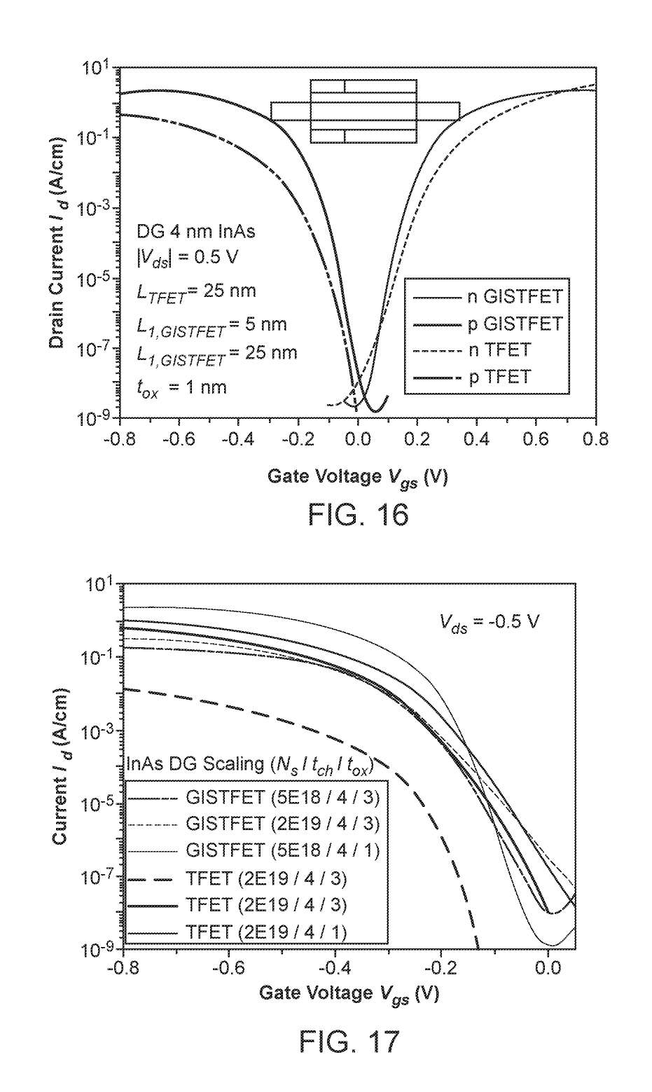

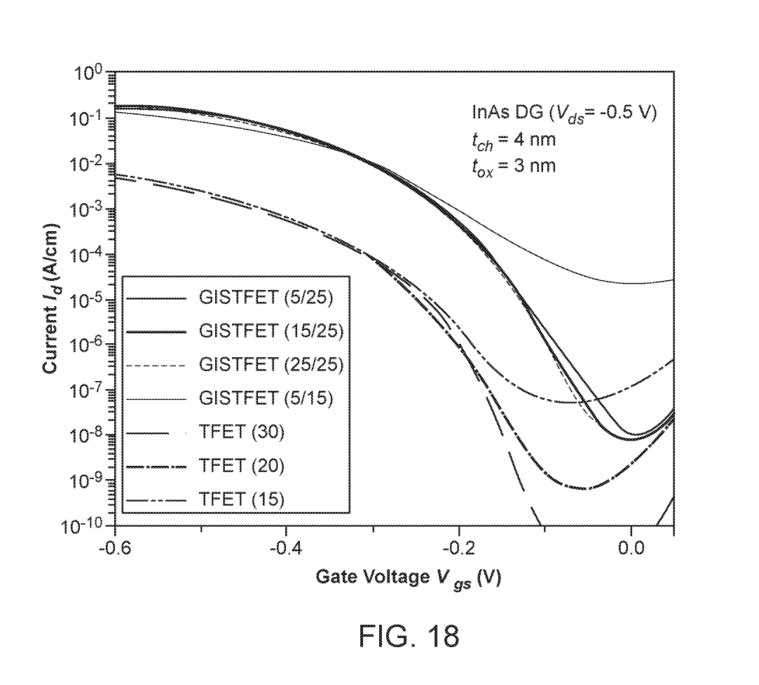

Similarly, k·p InAs NEGF simulations of GISTFETs are performed, using Φ=4.2 eV and 5.6 eV, which can be experimentally realized with Al and Pt respectively. Although InAs is attractive for TFETs due to its small band gap and effective mass, its low donor solubility (a feature of many III-V materials) and low conduction band density of states lead to strongly asymmetric n- and p-type devices as shown in FIG. 16. By contrast, the GISTFET leads to nearly perfectly symmetric n- and p-type operation with low contact doping, with on-off ratios in excess of 10⁹, minimum SS of about 20 mV/dec, and Iₒₙ of about 2.2 A/cm. The GISTFET's relative independence of source doping and strong improvement with geometric scaling is shown in FIG. 17. In FIG. 18, the similarities in GISTFET and TFET gate length scaling are illustrated; note that leakage increases at short lengths primarily due to the lack of an underlap or other drain-side engineering in the simulations.

### CONCLUSION

The GISTFET is proposed for steep SS, high current, and n- and p-type complementary devices substantially free of doping profile engineering. Quantum simulations confirm its advantages in both III-V semiconductors like InAs and 2-D materials like phosphorene.

As used herein, the singular terms “a,” “an,” and “the” include plural referents unless the context clearly dictates otherwise. Thus, for example, reference to an object can include multiple objects unless the context clearly dictates otherwise.

As used herein, the term “set” refers to a collection of one or more objects. Thus, for example, a set of objects can include a single object or multiple objects.

As used herein, the terms “substantially,” “substantial,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the terms “connect,” “connected,” and “connection” refer to an operational coupling or linking. Connected objects can be directly coupled to one another or can be indirectly coupled to one another, such as via another set of objects.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

While the disclosure has been described with reference to the specific embodiments thereof, it should be understood by those skilled in the art that various changes may be made and equivalents may be substituted without departing from the true spirit and scope of the disclosure as defined by the appended claims. In addition, many modifications may be made to adapt a particular situation, material, composition of matter, method, operation or operations, to the objective, spirit and scope of the disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations is not a limitation of the disclosure.

What is claimed is:

1. A tunneling field-effect transistor comprising:
a source region;
a drain region;
a channel region extending between the source region and the drain region;
a gate electrode spaced from the channel region; and
a dielectric layer disposed between the gate electrode and the channel region,
wherein the gate electrode includes a first section including a first conductive material M1 and a second section including a different, second conductive material M2, and the first section is electrically connected to the second section.

2. The tunneling field-effect transistor of claim 1, wherein the channel region includes a semiconductor having a bandgap E_{g}, and M1 and M2 have respective work functions Φ₁ and Φ₂ such that an absolute difference between the work functions |Φ₂−Φ₁| is greater than E_{g}.

3. The tunneling field-effect transistor of claim 1, wherein a) one of M1 and M2 is Al or Ti, and another one of M1 and M2 is Pt, Ni, or W; or b) wherein M1 or M2 is TiₓTa_{y}Al_{z}N.

4. The tunneling field-effect transistor of claim 1, further comprising a voltage source connected to the gate electrode, and configured to apply a common gate voltage to the first section and the second section.

5. The tunneling field-effect transistor of claim 4, wherein application of the common gate voltage is configured to induce a tunneling junction within the channel region.

6. The tunneling field-effect transistor of claim 5, wherein M1 and M2 form a heterojunction within the gate electrode, and the tunneling junction is aligned with the heterojunction.

7. The tunneling field-effect transistor of claim 6, wherein a length L_{M1} of the first section is the same as or different from a length L_{M2} of the second section.

8. The tunneling field-effect transistor of claim 7, wherein the tunneling junction is spaced from the source region by a distance corresponding to L_{M1}.

9. The tunneling field-effect transistor of claim 7, wherein the tunneling junction is spaced from the drain region by a distance corresponding to L_{M2}.

10. The tunneling field-effect transistor of claim 1, wherein the gate electrode and the dielectric layer correspond to a first gate electrode and a first dielectric layer, respectively, and further comprising:
a second gate electrode spaced from the channel region; and
a second dielectric layer disposed between the second gate electrode and the channel region,
wherein the second gate electrode includes a third section including a third conductive material M3 and a fourth section including a different, fourth conductive material M4, and the third section is electrically connected to the fourth section.

11. The tunneling field-effect transistor of claim 10, wherein M3 is the same as M1, and M4 is the same as M2.

12. The tunneling field-effect transistor of claim 1, wherein the gate electrode and the dielectric layer cover multiple surfaces of the channel region.

13. The tunneling field-effect transistor of claim 1, wherein the gate electrode and the dielectric layer surround the channel region.

14. The tunneling field-effect transistor of claim 1, wherein the channel region includes:
a Group III-V semiconductor;
a Group IV semiconductor; or
a two-dimensional or layered semiconductor.

15. The tunneling field-effect transistor of claim 1, wherein the channel region includes a first section including a first semiconductor S1 and a second section including a different, second semiconductor S2, and S1 and S2 form a heterojunction within the channel region.

16. The tunneling field-effect transistor of claim 1, wherein the tunneling field-effect transistor is p-type, M1 and M2 have respective work functions Φ₁ and Φ₂ such that Φ₂ is greater than Φ₁, the first section including M1 is adjacent to the source region, the second section including M2 is adjacent to the drain region, the source region is n-doped, and the drain region is p-doped.

17. The tunneling field-effect transistor of claim 1, wherein the tunneling field-effect transistor is n-type, M1 and M2 have respective work functions Φ₁ and Φ₂ such that Φ₁ is greater than Φ₂, the first section including M1 is adjacent to the source region, the second section including M2 is adjacent to the drain region, the source region is p-doped, and the drain region is n-doped.

18. The tunneling field-effect transistor of claim 1, wherein the drain region includes a lightly doped region adjacent to the channel region and a heavily doped contact region adjacent to the lightly doped region.

19. A tunneling field-effect transistor comprising:
a source;
a drain;
a channel extending between the source and the drain;
a gate electrode spaced from the channel; and
a dielectric layer disposed between the gate electrode and the channel,
wherein the gate electrode includes a first section adjacent to the source and a second section adjacent to the drain, and the first section and the second section include different materials forming a heterojunction between the first section and the second section.

20. The tunneling field-effect transistor of claim 19, wherein the different materials included in the first section and the second section have respective work functions Φ₁ and Φ₂ such that an absolute difference between the work functions |Φ₂−Φ₁| is greater than 0.5 eV.

21. A transistor operation method comprising:
providing a tunneling field-effect transistor including: a) a source region; b) a drain region; c) a channel region extending between the source region and the drain region; and d) a gate electrode spaced from the channel region by a dielectric layer, wherein the gate electrode includes a first section and a second section, the first section and the second section include different materials forming a heterojunction between the first section and the second section; and
applying a common gate voltage to the first section and the second section to induce a tunneling junction within the channel region and spaced from the source region and the drain region.

22. The method of claim 21, wherein the tunneling junction is aligned with the heterojunction.
